(19) United States
(12) Patent Application Publication
(10) Pub. No.: US 2004/0232438 A1
(43) Pub. Date: Nov. 25, 2004

(54) Semiconductor device and method for fabricating the same

(75) Inventor: Masahiro Ogawa, Osaka (JP)

Correspondence Address: Jack Q. Lever, Jr., McDERMOTT, WILL & EMERY, 600 Thirteenth Street, N.W., Washington, DC, 20005-3096, US

(73) Assignee: MATSUSHITA ELECTRIC INDUSTRIAL CO., LTD.

(21) Appl. No.: 10/849,053

(22) Filed: May 20, 2004

(30) Foreign Application Priority Data
May 23, 2003 (JP) 2003-145717

(51) Int. Cl. H01L 21/00; H01L 33/00

(52) U.S. Cl. 257/103; 438/22

(57) ABSTRACT

A semiconductor device includes an active layer constituted by a Group III nitride semiconductor layer containing at least three different elements including at least aluminum. The active layer exhibits a spatial fluctuation in the bandgap based on a variation of the aluminum content in the layer.

### BACKGROUND OF THE INVENTION

The present invention relates to semiconductor devices including nitride-based compound semiconductors for use as devices such as short-wavelength semiconductor lasers or light-emitting diodes and also relates to methods for fabricating the same.

Group III nitride-based compound semiconductors (hereinafter, simply referred to as nitride-based semiconductors) expressed as BₓAl_{y}Ga_{z}In_{1-x-y-z}N (where 0≦x≦1, 0≦y≦1, 0≦z≦1 and 0≦x+y+z≦1) are materials that cover wavelengths in the range from red to ultraviolet. Blue-light-emitting diodes and green-light-emitting diodes have been actualized to date, and nitride-based semiconductors are expected as materials for future optical devices capable of emitting light with a wider range of wavelengths.

In general, a nitride-based semiconductor device is fabricated on a sapphire substrate. In this case, the lattice constants of nitride-based semiconductor and sapphire differ largely, and thus a large number of dislocations are present in a film made of the nitride-based semiconductor. Despite this large difference, high-efficient light emission is achieved because of peculiar features of the nitride-based semiconductor. Specifically, a large lattice mismatch between GaN and InN, which constitute InGaN used for an active layer, prevents uniform mixture of GaN and InN so that a region having a high In content is locally formed. As a result, a spatial fluctuation (hereinafter, simply referred to as a fluctuation) is caused in the bandgap (see Japanese Unexamined Patent Publication No. 2001-345478, for example). In such a region having a high In content, the potential is lower than the potentials in the surrounding regions, so that electrons or holes are readily confined in the region with the high In content. Once electrons or holes are locally confined, these electrons or holes are less likely to be captured in a non-radiative recombination center resulting from, for example, dislocations, so that high-efficient light emission is implemented.

Such a nitride-based semiconductor device is generally fabricated using organic vapor phase epitaxy or molecular beam epitaxy.

As a technique for forming a film on the substrate, laser ablation is known (see Japanese Unexamined Patent Publication No. 6-293958, for example). Laser ablation is a process of depositing a film on a substrate by applying laser light onto a material to vaporize the material.

However, if AlGaN, which is a promising ultraviolet light source, is used for an active layer, a fluctuation is unlikely to occur in the bandgap, in contrast to the case of the aforementioned active layer of InGaN. This is because a compositional variation is unlikely to occur in the AlGaN layer and therefore electrons or holes are recombined without contributing to light emission in a non-radiative recombination center. Accordingly, if AlGaN is used for an active layer, a fluctuation is unlikely to occur in the bandgap, so that efficiency in light emission decreases.

It is still difficult to form a potential region in which electrons or holes are readily localized (i.e., to cause a fluctuation in the bandgap) through easy control of a compositional variation in a nitride-based semiconductor.

### SUMMARY OF THE INVENTION

It is therefore an object of the present invention to cause a fluctuation in the bandgap of a nitride-based semiconductor by easily controlling a compositional variation in the nitride-based semiconductor. This enhances the light emission efficiency of a nitride-based semiconductor device.

In order to achieve this object, through various studies, the present inventor found out that formation of mixed crystal of nitride-based semiconductors such as InGaN or AlGaN by laser ablation involves a variation in the composition of the mixed crystal so that a fluctuation occurs in the bandbgap.

Specifically, a semiconductor device according to the present invention includes an active layer constituted by a Group III nitride semiconductor layer containing at least three different elements including at least aluminum, wherein the active layer exhibits a fluctuation in the bandgap based on a variation in the distribution of the aluminum content in the active layer.

In the inventive semiconductor device, the variation of the aluminum content in the Group III nitride semiconductor layer causes a fluctuation in the bandgap in the active layer, so that electrons or holes are confined in a region having a narrow bandgap. Accordingly, electrons or holes which are locally confined are less likely to be captured in a non-radiative recombination center resulting from, for example, dislocations, so that the resultant semiconductor device implements high-efficient light emission.

A first method for fabricating a semiconductor device according to the present invention is a method for fabricating a semiconductor device including an active layer constituted by a Group III nitride semiconductor layer containing at least three different elements including at least aluminum. The step of forming the active layer includes the step of causing a fluctuation in the bandgap of the active layer by creating a variation in the distribution of the aluminum content in the active layer.

With the first inventive method, a variation in the distribution of the aluminum content in the Group III nitride semiconductor layer causes a fluctuation in the bandgap of the active layer, so that electrons or holes are confined in a region with a narrow bandgap. Accordingly, electrons or holes which are locally confined are less likely to be captured in a non-radiative recombination center resulting from, for example, dislocations, so that the resultant semiconductor device implements high-efficient light emission.

In the first inventive method, the step of forming the active layer preferably includes the step of applying laser light onto a target containing the elements of the active layer and vaporizing the element, thereby creating the variation in the distribution of the aluminum content in the active layer.

Then, the application of laser light allows a variation of the order of nanometers to be created in the distribution of the aluminum content in the active layer.

In the first inventive method, the target is preferably made of a material having a composition in which the ratio of a Group III element to a Group III nitride semiconductor, a Group III metal or a Group V element is greater than one.

Then, a variation is easily created in the distribution of the aluminum content in the active layer.

In the first inventive method, the step of forming the active layer is preferably performed in a nitrogen atmosphere.

A second method for fabricating a semiconductor device according to the present invention is a method including the step of forming an active layer constituted by a Group III nitride semiconductor layer. The step of forming the active layer includes the steps of: supplying a first material containing an element for the active layer such that the first material has a coverage ratio less than one with respect to an underlying layer; and supplying a second material which is different from the first material and contains an element for the active layer, after the step of supplying the first material has been performed.

With the second inventive method, the second material is supplied onto the principal surface formed by supplying the first material and having a coverage ratio less than one with respect to an underlying layer, so that a variation is easily created in the distribution of the content in the active layer. This causes a fluctuation in the bandgap of the active layer, so that electrons or holes are confined in a region with a narrow bandgap. Accordingly, electrons or holes which are locally confined are less likely to be captured in a non-radiative recombination center resulting from, for example, dislocations, so that the resultant semiconductor device implements high-efficient light emission. It should be noted that the coverage ratio is the area ratio of a deposition on the underlying layer to the underlying layer.

In the second inventive method, the step of supplying the first material preferably includes the step of supplying particles generated by decomposing the first material with heat.

Then, the material is easily supplied and a film exhibiting an excellent crystallinity is formed.

In the second inventive method, the step of supplying the second material preferably includes the step of supplying particles generated by decomposing the second material with heat.

Then, the material is easily supplied and a film exhibiting an excellent crystallinity is formed.

In the second inventive method, the particles preferably contain aluminum as an element.

In the second inventive method, the particles are preferably generated by applying laser light onto a target constituted by a Group III nitride semiconductor and vaporizing the Group III nitride semiconductor.

In the second inventive method, the particles are preferably generated by applying laser light onto a target constituted by a Group III metal and vaporizing the Group III metal.

In the second inventive method, the particles preferably have a composition in which the ratio of a Group III element to a Group V element is greater than one.

In the second inventive method, the step of forming the active layer is preferably performed in a nitrogen atmosphere.

### BRIEF DESCRIPTION OF THE DRAWINGS

FIG. 1 is a cross-sectional view showing a structure of an ultraviolet-light-emitting diode (LED) as an example of a semiconductor device to which methods for fabricating semiconductor devices according to embodiments of the present invention are applicable.

FIG. 2 is a cross-sectional view schematically showing laser ablation apparatus for use in the methods for fabricating the semiconductor devices according to the embodiments of the present invention.

FIGS. 3A through 3D are cross-sectional views showing a main portion in respective process steps in the methods for forming the semiconductor devices according to the embodiments of the present invention.

### DESCRIPTION OF THE PREFERRED EMBODIMENTS

Hereinafter, embodiments of the present invention will be described with reference to the drawings.

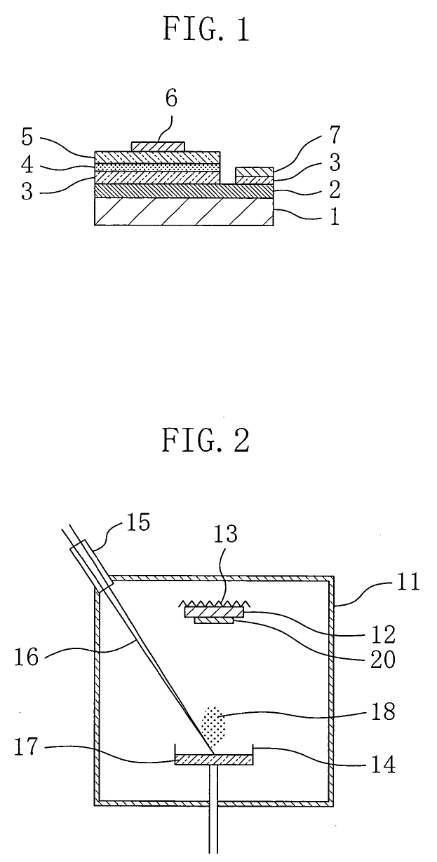

First, a specific device to which methods for fabricating semiconductor devices according to the following embodiments are applicable will be described with reference to FIG. 1 as an example.

FIG. 1 is a cross-sectional view showing a general structure of an ultraviolet-light-emitting diode (LED).

As shown in FIG. 1, a GaN layer 2 is formed on a sapphire substrate 1. A cladding layer 3 made of an n-AlGaN layer, an active layer 4 of AlGaN and a cladding layer 5 of p-AlGaN are stacked in this order over the GaN layer 2. A p-type electrode 6 is formed on the cladding layer 5. An n-type electrode 7 is formed on the cladding layer 3 on the GaN layer 2.

In this manner, the light-emitting diode shown in FIG. 1 has a multilayer structure of AlGaN. Examples of devices having similar structures include semiconductor laser diodes (LDs), field effect transistors (FETs) and bipolar transistors as well as LEDs. The following methods for fabricating semiconductor devices are applicable to methods for fabricating these devices and relate to methods for forming the aforementioned active layer 4 of AlGaN.

Hereinafter, respective embodiments will be described specifically.

### EMBODIMENT 1

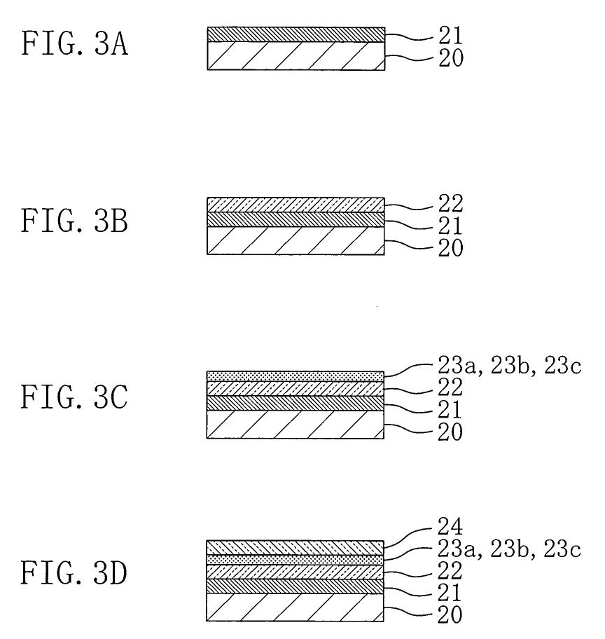

Hereinafter, a method for fabricating a semiconductor device according to the present invention will be described with reference to FIG. 2 and FIGS. 3A through 3D. FIG. 2 is a view schematically showing a structure of laser ablation apparatus. FIGS. 3A through 3D are cross-sectional views showing a main portion in respective process steps in the method for fabricating the semiconductor device according to the present invention.

Now, the laser ablation apparatus will be described.

As shown in FIG. 2, a susceptor 12 for mounting a substrate thereon and a heater 13 for heating the substrate are placed in a chamber 11. A plurality of stainless disks 14 for holding targets are arranged to face the susceptor 12. Laser light 16 incident from the outside are focused through an optical window 15 of quartz and applied onto a target 17, thereby ablating materials from the target 17. Each of the disks 14 for mounting respective targets 17 thereon is configured to rotate about its center axis.

Now, a method for fabricating the semiconductor device of the present invention using the laser ablation apparatus will be described specifically with reference to FIG. 2 and FIGS. 3A through 3D.

First, a sapphire substrate 20 which has a diameter of two inches and whose principal surface is a C-plane is placed on the susceptor 12 in the chamber 11 of the laser ablation apparatus (see FIG. 2). Subsequently, the chamber 11 is evacuated sufficiently by a vacuum pump and then the sapphire substrate 20 is heated to 1050° C. Thereafter, nitrogen is introduced into the chamber 11 and the degree of vacuum in the chamber 11 is kept at 6.65×10⁻⁴ Pa. As a laser for use in laser ablation, an ArF excimer laser (wavelength: 193 nm, energy density: 1 J/cm² and frequency: 100 Hz) is used.

Next, the GaN target 17 is irradiated with the laser light 16 (see FIG. 2). In this case, the surface of the GaN target 17 is rapidly heated in part by the laser light 16, thereby generating a group of particles of, for example, electrons, atoms, molecules or ions, which is called a plume 18. The plume 18 travels to the sapphire substrate 20 that faces the target 17, being colliding and reacting with nitrogen in the atmosphere, and forms an aggregation again, so that a GaN layer 21 is formed. Specifically, the GaN layer 21 having a thickness of 1 μm is formed on the sapphire substrate 20 (see FIG. 3A). Alternatively, the GaN layer 21 may be formed on a buffer layer of AlN or GaN formed on the sapphire substrate 20.

Then, the heater 13 is operated such that the temperature of the sapphire substrate 20 is raised to 1200° C., and then as the target 17, the GaN target is replaced with a silicon-doped n-type AlGaN target having an Al content of 20%. Thereafter, the n-type AlGaN target 17 is irradiated with laser light 16 so that n-type AlGaN is vaporized, thereby forming an n-type AlGaN layer 22 with a thickness of 500 nm on the GaN layer 21 (see FIG. 3B).

Thereafter, as the target 17, the silicon-doped n-type AlGaN target having an Al content of 20% is replaced with a target consisting of an Al target member and an AlGaN target member having an Al content of 10% and each of the target members constitutes half of the target. Subsequently, laser light 16 is applied onto the target 17 with the target 17 rotated at a rotation speed of 120 rpm, thereby forming an undoped AlGaN layer 23a serving as an active layer and having a thickness of 30 nm on the n-type AlGaN layer 22 (see FIG. 3C).

Now, the AlGaN layer 23a will be described specifically.

When the Al target member constituting half of the target 17 is irradiated with the laser light 16, the plume 18 ejected from the Al target reacts with nitrogen in an atmosphere from the periphery of the plume 18, thereby generating AlNₓ (where 0<x<1) containing an excessive amount of Al. On the other hand, when the AlGaN target member constituting the other half of the target 17 is irradiated with the laser light 16, AlGaN reflecting the composition of the AlGaN target member is generated from the AlGaN target member. Accordingly, an undoped AlGaN layer 23a including a region of the order of nanometers containing an excessive amount of Al is formed on the n-type AlGaN layer 22. The bandgap of AlGaN locally increases near the Al-excess region, so that a fluctuation is caused in the bandgap of the AlGaN layer 23a. In this manner, a variation in the distribution of the Al content of the order of nanometers occurs in the AlGaN layer 23a, thus causing a fluctuation in the bandgap of the AlGaN layer 23a.

Specifically, in the laser ablation, the laser light 16 converged through the optical window 15 of quartz is introduced into the chamber 11 from the outside and is applied onto the surface of a solid material (i.e., the surface of the target 17) placed in the chamber 11, so that the material is rapidly heated in part at its surface by the laser light 16 to be vaporized and emitted to the atmosphere. Accordingly, the composition of ejected atoms reflects the composition of the target 17, almost independently of the vapor pressures and the like of atoms constituting the target 17. This makes it easier to control the compositions of elements constituting the active layer (the AlGaN layer 23a), so that a variation is easily created in the compositional distribution. As a result, a fluctuation is easily caused in the bandgap of the active layer (the AlGaN layer 23a). In addition, a material for use in the laser ablation is commonly supplied to a plurality of apparatus, so that the material is replaced easily and mutual contamination is prevented.

As a method for creating a variation in the distribution of the Al content in the AlGaN layer 23a, the following method may be also adopted.

That is, a material, e.g., Al, containing an element constituting the AlGaN layer 23a is supplied onto the n-type AlGaN layer 22 such that the coverage ratio with respect to the n-type AlGaN layer 22 as an underlying layer is less than one. Then, a material containing AlGaN is supplied, thereby forming the AlGaN layer 23. In this manner, a variation of the order of nanometers is created in the distribution of the Al content in the AlGaN layer 23a, thus causing a fluctuation in the bandgap of the AlGaN layer 23a.

Next, as the target 17, the target consisting of the Al target member and the AlGaN target member having an Al content of 10% is replaced with a target of p-type AlGaN having an Al content of 20%. The p-type AlGaN target is irradiated with laser light 16 so that p-type AlGaN is vaporized, thereby forming a p-type AlGaN layer 24 having a thickness of 500 nm on the AlGaN layer 23a (see FIG. 3D). In this manner, a double heterostructure as shown in FIG. 3D is formed.

On a device having a double heterostructure as shown in FIG. 3D, electrodes as shown in FIG. 1 were formed and then a voltage was applied thereto. Then, the resultant luminous intensity was about 10 times as great as that in a case where no Al-excess region is formed in the AlGaN layer 23a.

As described above, according to the first embodiment, a variation is created in the distribution of the Al content in the AlGaN layer 23a as an active layer, so that a fluctuation occurs in the bandgap of the AlGaN layer 23a. Since electrons or holes are present in portions of the fluctuation of the bandgap where the potential is low, the electrons or holes are less likely to be captured in a non-radiative recombination center. Accordingly, the light emission efficiency improves. The formation of the AlGaN layer 23a by laser ablation makes it easier to create a variation in the distribution of the Al content in the AlGaN layer 23a.

In this embodiment, to form the AlGaN layer 23a, the target consisting of the Al target member and the AlGaN target member each constituting half of the target is used as the target 17. Alternatively, a target consisting of a Ga target member and an AlGaN target member each constituting half of the target may be used. In such a case, a region of the order of nanometers containing an excessive amount of Ga is formed in the AlGaN layer, and the bandgap of the AlGaN layer is narrow in a portion near the Ga-excess region. Even in such a case of using a target consisting of the Ga target member and the AlGaN target member each constituting half of the target, a fluctuation is caused in the bandgap of the AlGaN layer. As a metal target member constituting half of the target 17, an Al target member or a Ga target member is used in this embodiment. However, the metal target member is not limited to one type and both metals of Al and Ga may be used.

In this embodiment, the target consisting of two types of target members each constituting half of the target is used to form the AlGaN layer 23a. However, each of the target members does not necessarily constitute half of the target. The density in the excess region can be changed by adjusting the size ratio between the target members.

If the dilution ratio of nitrogen atmospheric gas is adjusted in forming the AlGaN layer 23a, the density in the Al-excess region can be changed. Specifically, if the ratio of a rare gas such as He or Ne is increased, metal atoms are allowed to be supplied without a reaction with the nitrogen atmospheric gas. Under an atmosphere exclusively containing a rare gas, the metal atoms are supplied without change, so that metal droplets are formed in the film.

### EMBODIMENT 2

Hereinafter, a method for fabricating a semiconductor device according to a second embodiment of the present invention will be described with reference to FIG. 2 and FIGS. 3A through 3D.

First, as the method for fabricating the semiconductor device of the second embodiment, a GaN layer 21 and an n-type AlGaN layer 22 are deposited in this order by laser ablation over a sapphire substrate 20, as in the first embodiment (see FIGS. 3A and 3B).

Next, as a target 17, a target consisting of an AlₓGa₁₋ₓN (where x=0.0095) target member and an Al_{y}Ga_{1-y}N (where y=0.01) target member each constituting half of the target is used. Then, laser light 16 is applied onto the target 17 with the target 17 rotated at a rotation speed of 120 rpm, thereby forming an undoped AlGaN layer 23b with a thickness of 30 nm on the n-type AlGaN layer 22 (see FIG. 3C). Use of the target 17 made of two types of nitride-based semiconductors having different compositions allows the formation of the undoped AlGaN layer 23b in which the two types of nitride-based semiconductors are mixed. Specifically, in the AlGaN layer 23b, AlₓGa₁₋ₓN (where x=0.0095) and Al_{y}Ga_{1-y}N (where y=0.01) are mixed and regions of the order of nanometers having different compositions depending on the location are formed. Accordingly, the AlGaN layer 23b exhibits a fluctuation in the bandgap, reflecting the bandgaps of the two types of nitride-based semiconductors. In this manner, a variation in the distribution of the Al content is created in the AlGaN layer 23b, so that a fluctuation is caused in the bandgap of the AlGaN layer 23b.

Then, as the target 17, the target consisting of the AlₓGa₁₋ₓN (where x=0.0095) target member and the Al_{y}Ga_{1-y}N (where y=0.01) target member each constituting half of the target is replaced with a target of p-type AlGaN having an Al content of 20%. Subsequently, laser light 16 is applied onto the p-type AlGaN target to vaporize p-type AlGaN, thereby forming a p-type AlGaN layer 24 with a thickness of 500 nm on the AlGaN layer 23b (see FIG. 3D). In this manner, a double heterostructure shown in FIG. 3D is formed.

On a device having such a double heterostructure, electrodes as shown in FIG. 1 were formed and then a voltage was applied thereto. Then, the resultant luminous intensity was about 10 times as great as that in a case where one type of AlGaN target is used as the target 17. This is because a fluctuation of the bandgap is locally caused in the undoped AlGaN layer 23b as an active layer so that electrons or holes are localized to be less likely to be captured in a non-radiative recombination center and thereby the light emission efficiency is increased.

As described above, according to the second embodiment, a variation is created in the distribution of the Al content in the AlGaN layer 23b as an active layer, so that a fluctuation occurs in the bandgap of the AlGaN layer 23b. Since electrons or holes are present in portions where the potential is low in the fluctuation of the bandgap, these electrons or holes are less likely to be captured in a non-radiative recombination center. Accordingly, the light emission efficiency is enhanced. The formation of the AlGaN layer 23b by laser ablation makes it easier to create a variation in the distribution of the Al content in the AlGaN layer 23b.

In this embodiment, to form the AlGaN layer 23b, the target consisting of two types of target members each constituting half of the target is used. However, each of the target members does not necessarily constitute half of the target. The density in the excess region can be changed by adjusting the size ratio between the target members.

If the dilution ratio of nitrogen atmospheric gas is adjusted in forming the AlGaN layer 23b, the density in the Al-excess region can be changed. Specifically, if the ratio of a rare gas such as He or Ne is increased, metal atoms are allowed to be supplied without a reaction with the nitrogen atmospheric gas. Under an atmosphere exclusively containing a rare gas, the metal atoms are supplied without change, so that metal droplets are formed in the film.

### EMBODIMENT 3

Hereinafter, a method for fabricating a semiconductor device according to a third embodiment of the present invention will be described with reference to FIG. 2 and FIGS. 3A through 3D.

First, as the method for fabricating the semiconductor device of the third embodiment, a GaN layer 21 and an n-type AlGaN layer 22 are deposited in this order by laser ablation over a sapphire substrate 20, as in the first embodiment (see FIGS. 3A and 3B).

Next, as a target 17, an Al_{0.10}Ga_{0.90}N_{0.98} target whose composition deviates from stoichiometry due to a deficiency of nitrogen is used. Specifically, the chemical composition ratio of Group III atoms to Group V atoms is one in general, but the deficiency of nitrogen causes the ratio of Group III atoms to Group V atoms to fall below one. Then, laser light 16 is applied onto the target 17 with the target 17 rotated at a rotation speed of 120 rpm, thereby forming an undoped AlGaN layer 23c with a thickness of 30 nm. In this case, a plume 18 is generated by the application of the laser light 16 onto the target 17 and reacts with nitrogen in an atmospheric gas from the periphery of the plume 18 to compensate for the deficiency of nitrogen. On the other hand, the center of the plume 18 is shielded from the atmospheric gas, so that the center of the plume 18 still lacks nitrogen. Accordingly, the AlGaN layer 23c is formed as a film including both a region compensated for its deficiency of nitrogen and a region lacking in nitrogen. In this manner, a variation of the order of nanometers is created in the distribution of the Al content in the AlGaN layer 23c, so that a fluctuation is caused in the bandgap of the AlGaN layer 23c.

Then, the Al_{0.10}Ga_{0.09}N_{0.98} target whose composition deviates from stoichiometry due to a deficiency of nitrogen is replaced with a target of p-type AlGaN having an Al content of 20%. Then, laser light 16 is applied onto the p-type AlGaN target to vaporize p-type AlGaN, thereby forming a p-type AlGaN layer 24 with a thickness of 500 nm on the AlGaN layer 23c (see FIG. 3D). In this manner, a double heterostructure shown in FIG. 3D is formed.

On a device having such a double heterostructure, electrodes as shown in FIG. 1 were formed and then a voltage was applied thereto. Then, the resultant luminous intensity was about 10 times as great as that in a case where a general AlGaN target whose composition does not deviate from stoichiometry is used as the target 17. This is because a fluctuation of the bandgap locally occurs in the AlGaN layer 23c as an active layer so that electrons or holes are localized to be less likely to be captured in a non-radiative recombination center and thereby the light emission efficiency is enhanced.

As described above, according to the third embodiment, a variation is created in the distribution of the Al content in the AlGaN layer 23c as an active layer, so that a fluctuation occurs in the bandgap of the AlGaN layer 23c. Since electrons or holes are present in portions where the potential is low in the fluctuation of the bandgap, these electrons or holes are less likely to be captured in a non-radiative recombination center. Accordingly, the light emission efficiency improves. The formation of the AlGaN layer 23c by laser ablation makes it easier to create a variation in the distribution of the Al content in the AlGaN layer 23c.

In the foregoing embodiments, a series of processes for depositing the films is performed by laser ablation. Alternatively, other deposition methods may be used. Even if an MOVPE or MBE process is used and materials are alternately supplied, the present invention is still carried out in the same manner.

In the foregoing embodiments, the ArF excimer laser is used as a laser for use in laser ablation. Alternatively, other ultraviolet lasers may be used. For example, an excimer laser using, for example, XeCl (wavelength: 308 nm) or KrF (wavelength: 248 nm) or a YAG laser using the fourth harmonic (wavelength: 266 nm) may be used.

In the foregoing embodiments, the AlGaN layer is used as an active layer. Alternatively, the active layer may be made of BₓAl_{y}Ga_{z}In_{1-x-y-z}N (where 0≦x≦1, 0≦y≦1, 0≦z≦1 and 0≦x+y+z≦1). In this case, the present invention is still carried out in the same manner.

With the semiconductor devices and the methods for fabricating the devices according to the present invention, a variation of the aluminum content in a Group III nitride semiconductor layer causes a fluctuation in the bandgap of the active layer, so that electrons or holes are confined in a region having a narrow bandgap. Accordingly, once electrons or holes are locally confined, these electrons or holes are less likely to be captured in a non-radiative recombination center resulting from, for example, dislocations, so that high-efficient light emission is implemented.

As described above, the present invention is applicable to semiconductor devices having multilayer structures of nitride-based semiconductors, e.g., LEDs, semiconductor laser diodes (LDs), field effect transistors (FETs) and bipolar transistors.

What is claimed is:

1. A semiconductor device, comprising an active layer constituted by a Group III nitride semiconductor layer containing at least three different elements including at least aluminum,
wherein the active layer exhibits a fluctuation in the bandgap based on a variation in the distribution of the aluminum content in the active layer.

2. A method for fabricating a semiconductor device including an active layer constituted by a Group III nitride semiconductor layer containing at least three different elements including at least aluminum,
the method comprising the step of forming the active layer,
wherein the step of forming the active layer includes the step of causing a fluctuation in the bandgap of the active layer by creating a variation in the distribution of the aluminum content in the active layer.

3. The method of claim 2, wherein the step of forming the active layer includes the step of applying laser light onto a target containing the elements of the active layer and vaporizing the element, thereby creating the variation in the distribution of the aluminum content in the active layer.

4. The method of claim 3, wherein the target is made of a material having a composition in which the ratio of a Group III element to a Group III nitride semiconductor, a Group III metal or a Group V element is greater than one.

5. The method of claim 2, wherein the step of forming the active layer is performed in a nitrogen atmosphere.

6. A method for fabricating a semiconductor device, the method comprising the step of forming an active layer constituted by a Group III nitride semiconductor layer,
wherein the step of forming the active layer includes the steps of:
supplying a first material containing an element for the active layer such that the first material has a coverage ratio less than one with respect to an underlying layer; and
supplying a second material which is different from the first material and contains an element for the active layer, after the step of supplying the first material has been performed.

7. The method of claim 6, wherein the step of supplying the first material includes the step of supplying particles generated by decomposing the first material with heat.

8. The method of claim 6, wherein the step of supplying the second material includes the step of supplying particles generated by decomposing the second material with heat.

9. The method of claim 7 or 8, wherein the particles contain aluminum as an element.

10. The method of claim 7 or 8, wherein the particles are generated by applying laser light onto a target constituted by a Group III nitride semiconductor and vaporizing the Group III nitride semiconductor.

11. The method of claim 7 or 8, wherein the particles are generated by applying laser light onto a target constituted by a Group III metal and vaporizing the Group III metal.

12. The method of claim 7 or 8, wherein the particles have a composition in which the ratio of a Group III element to a Group V element is greater than one.

13. The method of claim 6, wherein the step of forming the active layer is performed in a nitrogen atmosphere.
